(19) United States
(12) Patent Application Publication
(10) Pub. No.: US 2023/0101340 A1
(43) Pub. Date: Mar. 30, 2023

(54) MULTICHIP PACKAGE STAIRCASE CAVITIES

(71) Applicant: Intel Corporation, Santa Clara, CA (US)

(72) Inventors: Kaveh HOSSEINI, San Jose, CA (US); Omkar KARHADE, Chandler, AZ (US); Ravindranath V. MAHAJAN, Chandler, AZ (US); Sergey Yuryevich SHUMARAYEV, Los Altos Hills, CA (US); Yew F. KOK, Newark, CA (US); Sai VADLAMANI, Gilbert, AZ (US)

(21) Appl. No.: 17/485,295

(22) Filed: Sep. 24, 2021

(51) Int. Cl. H01L 25/065; H01L 23/00; H01L 21/48; H01L 25/00

(52) U.S. Cl. CPC H01L 25/0657; H01L 24/16; H01L 24/32; H01L 21/485; H01L 24/81; H01L 24/83; H01L 25/50; H01L 24/73; H01L 2225/06562; H01L 2224/16225; H01L 2224/16145; H01L 2224/32225; H01L 2225/06541; H01L 2225/06517; H01L 2225/06513; H01L 2224/73204

(57) ABSTRACT

Embodiments disclosed herein include electronic packages and methods of assembling an electronic package. In an embodiment, an electronic package comprises a package substrate with a stepped top surface, and a first die on a first plateau of the stepped top surface. In an embodiment, a second die is on a second plateau of the stepped top surface, where the second die extends over the first die, In an embodiment, a third die is on a third plateau of the stepped top surface, where the third die extends over the second die.

### GOVERNMENT LICENSE RIGHTS

This invention was made with Government support under Agreement No. HR0011-19-3-0003, awarded by DARPA. The Government has certain rights in the invention.

### TECHNICAL FIELD

Embodiments of the present disclosure relate to electronic packages, and more particularly to multichip electronic packages with a stepped top surface.

### BACKGROUND

As technology continues to advance, multichip heterogeneous integration has become more common. In the particular instance of photonic systems, components such as a photonics integrated circuit (PIC), an electrical integrated circuit (EIC), and a logic die (e.g., a field programmable gate array (FPGA)) may be integrated within a single package architecture. In order to provide high density interconnects between the components, solutions such as embedded multi-die interconnect bridge (EMIR) have been proposed.

However, the EMIB architecture results in non-optimal package form factor and power consumption. In the case of form factor, the EMIB approach relies on components being laterally adjacent to each other, and the EMIR stitches neighboring components together. As such, a large X-Y footprint is needed. In the case of power consumption, the electrical path across the EMIB increases the power consumption due to losses across the EMIB. Particularly, in the case of a photonics system, the signal must pass from the PIC to the EIC across a first EMIB, and from the EIC to the logic die across a second EMIB.

### BRIEF DESCRIPTION OF THE DRAWINGS

FIG. 1 is a cross-sectional illustration of an electronic package with a photonics integrated circuit (PIC), an electrical integrated circuit (EIC), and a logic die that are interconnected by a pair of embedded multi-die interconnect bridges (EMIBs).

FIG. 2 is a cross-sectional illustration of an electronic package with a PIC, an EIC, and a logic die with the PIC directly connected to the EIC, and the EIC connected to the logic die through an EMIB.

FIG. 3 is a cross-sectional illustration of an electronic package with a PIC, an EIC, and a logic die that are all directly connected to each other by using a stepped package substrate, in accordance with an embodiment.

FIG. 4A-4J are cross-sectional illustrations depicting a process for assembling an electronic package with a stepped top surface that comprises a PIC, an EIC, and a logic die, in accordance with an embodiment.

FIG. 5 is a cross-sectional illustration of an electronic package with a PIC that is adhered to the package substrate by a die attach film (DAF), in accordance with an embodiment.

FIG. 6 is a cross-sectional illustration of an electronic system with the logic die and the EIC attached to the package substrate and the PIC attached to the underlying board, in accordance with an embodiment.

FIG. 7 is a cross-sectional illustration of an electronic system with electronic package with a PIC, an EIC, and a logic die that is coupled to a board, in accordance with an embodiment.

FIG. 8 is a schematic of a computing device built in accordance with an embodiment.

### EMBODIMENTS OF THE PRESENT DISCLOSURE

Described herein are multichip electronic packages with a stepped top surface, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

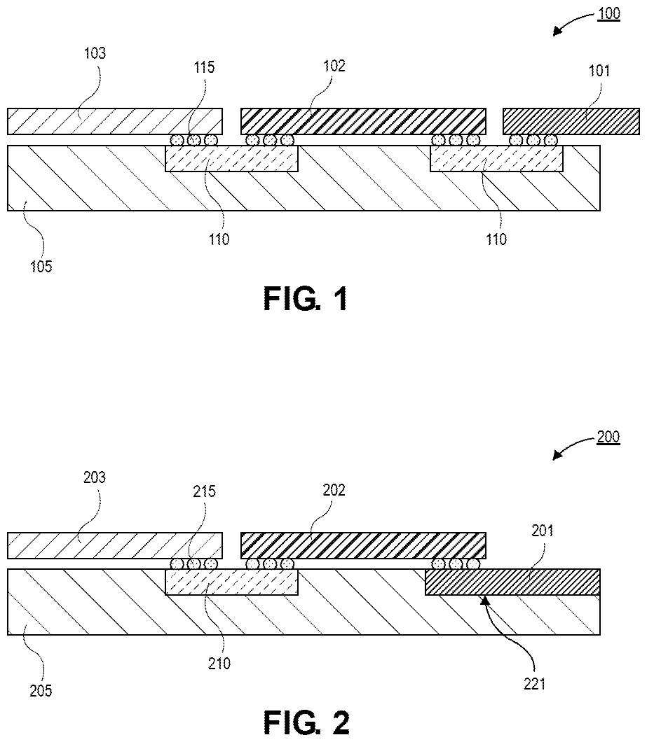

An example of a heterogeneous package with a logic die, an electrical integrated circuit (EIC), and a photonics integrated circuit (PIC) is shown in FIG. 1. As shown, the package 100 includes a package substrate 105. The PIC 101 is connected to the EIC 102 through solder interconnects 115 and a first embedded multi-die interconnect bridge (EMIB) 110. Additionally, the EIC 102 is connected to the logic die 103 through interconnects 115 and a second EMIB 110. Such an architecture requires the logic die 103, the EIC 102, and the PIC 101 to be laterally adjacent to each other. Additionally, the electrical path through the EMIBs increases the path length and increases losses.

In order to reduce the lateral footprint and eliminate one of the EMIBs 110, a stacked architecture may be used. An example of such a package 200 is shown in FIG. 2. As shown, the PIC 201 is embedded in the package substrate 205. That is, a surface 221 on which the PIC 201 is supported is below the top surface of the package substrate 205. However, in such an architecture, the EIC 202 is still coupled to the logic die 203 by an EMIB 210 and interconnects 215. Accordingly, there are still significant area and power penalties to such a design.

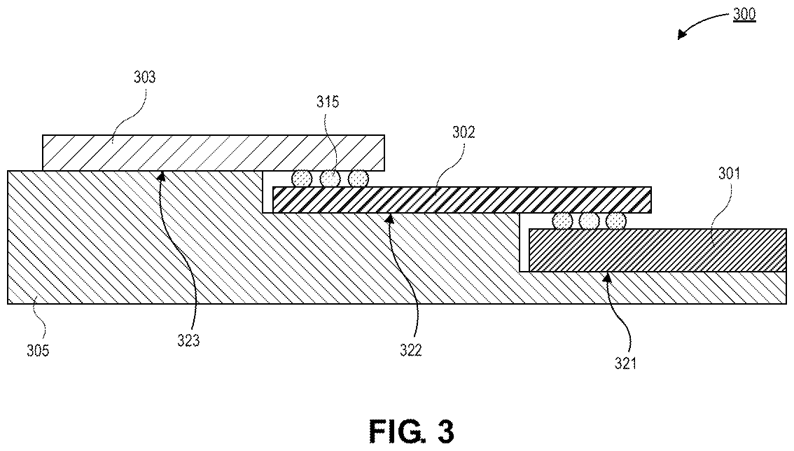

Referring now to FIG. 3, a cross-sectional illustration of an electronic package 300 is shown, in accordance with an embodiment. In an embodiment, the electronic package 300 comprises a package substrate 305. The package substrate 305 is shown as a solid block in FIG. 3. However, it is to be appreciated that the package substrate 305 may comprise electrical routing (e.g., pads, vias, traces, etc.) embedded in a plurality of organic layers. In an embodiment, the package substrate 305 may be a cored package substrate 305.

In an embodiment, the package substrate 305 may have a stepped top surface. As used herein, a stepped surface may refer to a surface that includes two or more plateaus that are connected to each other by a vertical surface. A vertical surface may be a substantially vertical surface or a sloped surface that has a vertical component. For example, the package substrate 305 has a stepped surface that includes three plateaus. A first plateau 321, a second plateau 322, and a third plateau 323 are shown in FIG. 3.

In an embodiment, a first die 301 may be provided on the first plateau 321, a second die 302 may be provided on the second plateau 322, and a third die 303 may be provided on the third plateau 323. The first die 301 may be a PIC, the second die 302 may be an EIC, and the third die 303 may be a logic die (e.g., an FPGA). However, it is to be appreciated that the dies 301, 302, and 303 may be any suitable type of dies that are heterogeneously integrated in the electronic package 300.

In an embodiment, an entirety of the first die 301 may be over the first plateau 321. In the illustrated embodiment, an edge of the first die 301 is substantially coplanar with an edge of the package substrate 305. However, in other embodiments, the first die 301 may overhang the edge of the package substrate. In an embodiment, the second die 302 may be over the second plateau 322 and extend over a portion of the first die 301. The first die 301 may be electrically coupled to the second die 302 by interconnects 315. As such, a direct coupling is provided between the first die 301 and the second die 302 without the need to pass over a bridge substrate. Additionally, the overlap between the first die 301 and the second die 302 reduces the combined footprint of the first die 301 and the second die 302, compared to when an EMIB architecture is used to connect the first die 301 to the second die 302. In an embodiment, the third die 303 is on the third plateau 323 and extends over a portion of the second die 302. The second die 302 may be electrically coupled to the third die 303 by interconnects 315. As such, a direct coupling is provided between the second die 302 and the third die 303 without the need to pass over a bridge substrate. Additionally, the overlap between the second die 302 and the third die 303 reduces the combined footprint of the second die 302 and the third die 303, compared to when an EMIR architecture is used to connect the second die 302 to the third die 303.

In FIG. 3, the only connections that are shown are the interconnects 315 between the dies 301, 302, and 303. However, it is to be appreciated that the dies 301 may also be electrically connected to circuitry (not shown) within the package substrate 305. Additionally through silicon vias (TSVs) may be provided through the thickness of one or more of the dies 301, 302, and 303. For example, TSVs may be provided through the second die 302 either above the first die 301 and/or below the third die 303.

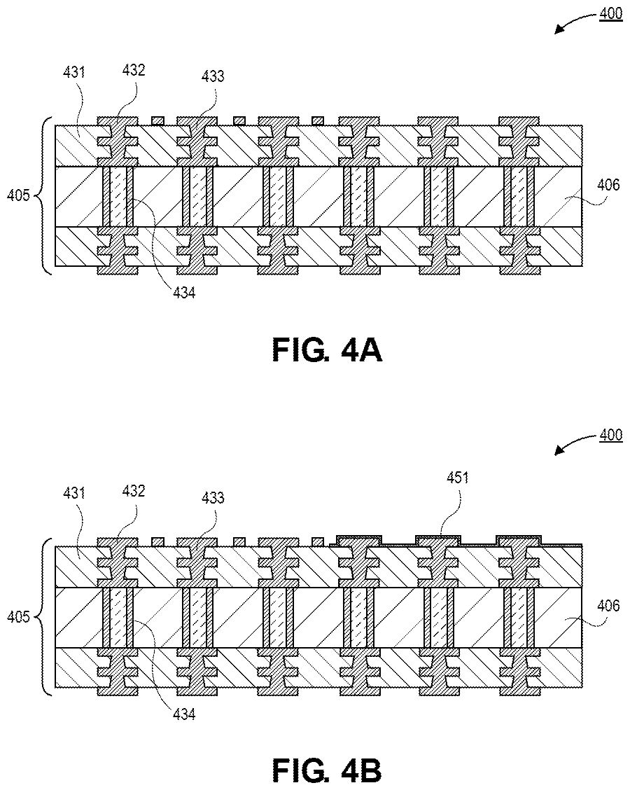

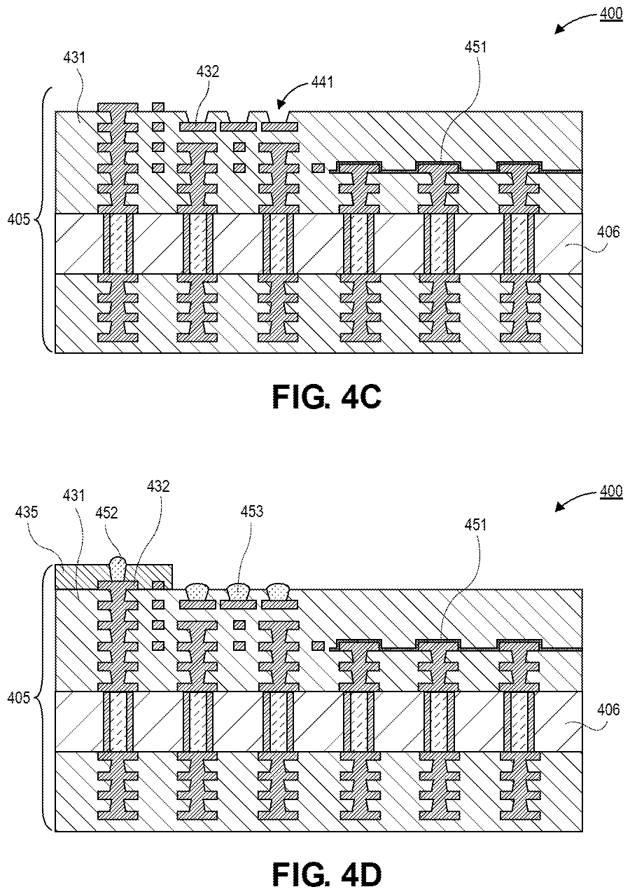

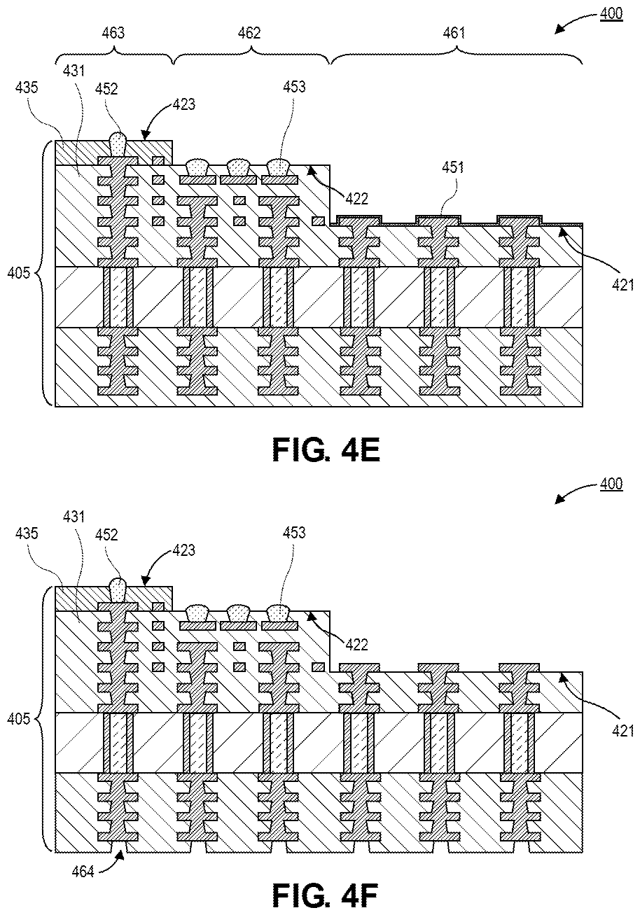

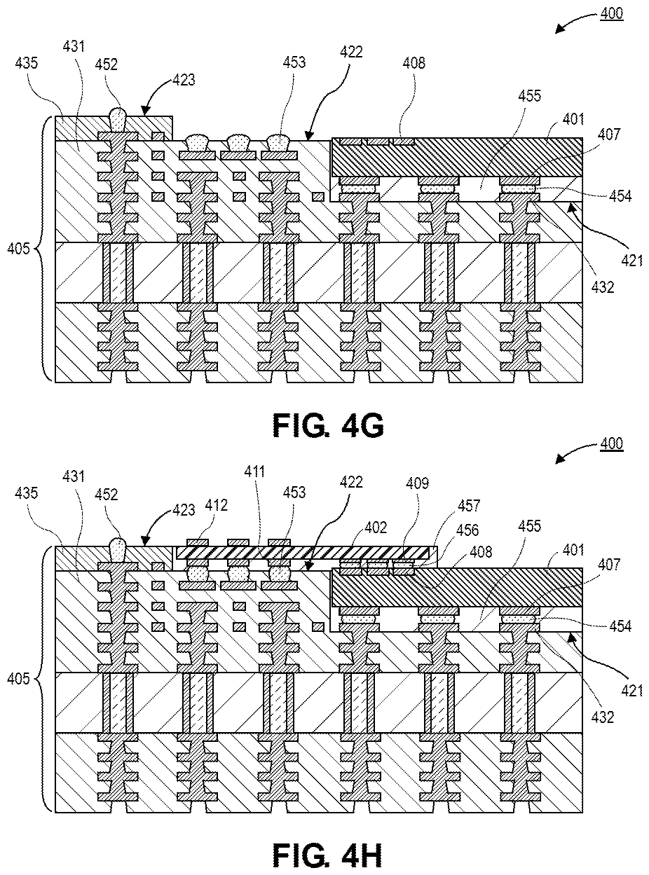

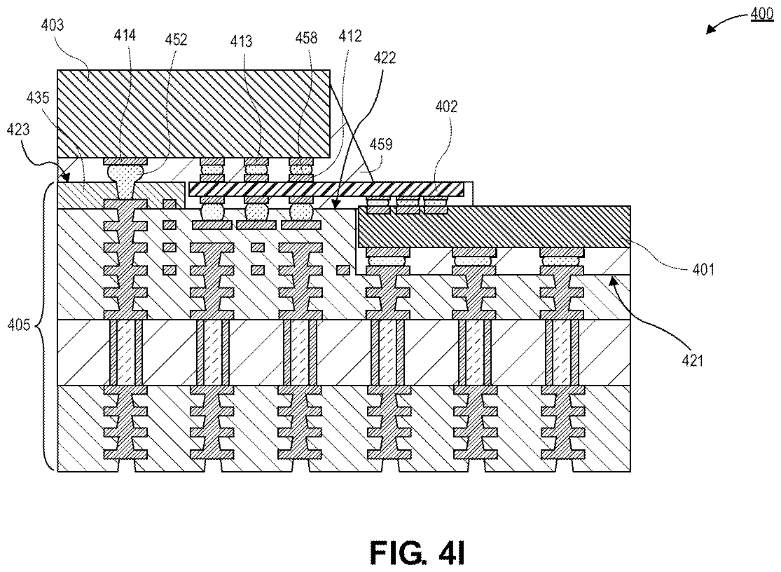

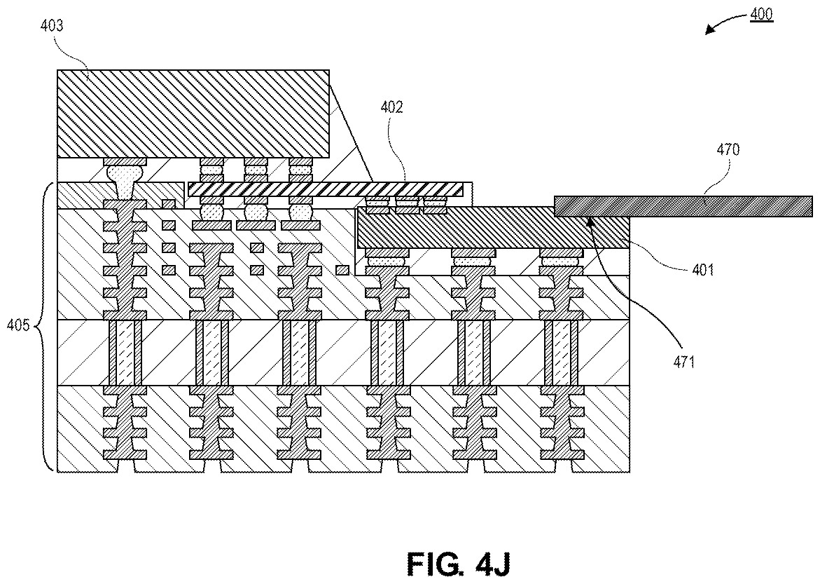

A more detailed illustration of an electronic package 400 is shown in the process flow depicted in FIGS. 4A-4J. Whereas FIG. 3 is a generic representation of the positional relationship of the dies 301, 302, and 303 with respect to each other, FIGS. 4A-4J provide a more detailed illustration of the package substrate and the interconnects between the package substrate and the dies 401, 402, and 403.

Referring now to FIG. 4A, a cross-sectional illustration of a portion of an electronic package 400 is shown, in accordance with an embodiment. In an embodiment, the electronic package 400 comprises a package substrate 405. The package substrate 405 may comprise a core 406. The core 406 may comprise a glass reinforced organic material, common to electronic packaging architectures. Through core vias 434 may be provided through the core 406 to provide electrical coupling between a backside of the package substrate 405 and a front side of the package substrate. In an embodiment, buildup layers 431 may also be provided above and below the core 406. The buildup layers 431 may be organic material such as buildup film or the like. In an embodiment, pads 432 and vias 433 may be provided in the buildup layers 431. Traces may also be provided in the buildup layers.

In the illustrated embodiment, three routing layers are shown above and below the core 406. However, it is to be appreciated that any number of routing layers may be provided above and/or below the core 406. Additionally, the number of routing layers above the core 406 may be different than the number of routing layers below the core 406.

Referring now to FIG. 4B, a cross-sectional illustration of the electronic package 400 after a release layer 451 is formed is shown, in accordance with an embodiment. As shown, the release layer 451 is provided over a portion of the package substrate 405. The region covered by the release layer 451 will ultimately become the first plateau on which the first die will be mounted. In an embodiment, a first end of the release layer 451 is located towards a middle of the package substrate 405, and a second end of the release layer 451 is located at an edge of the package substrate 405. As such, the resulting plateau formed with the release layer 451 will extend to the edge of the package substrate 405.

The release layer 451 may be any suitable release layer material that allows for buildup material to be removed while not damaging the underlying pads 432. For example, the release layer material may be an organic layer which does not adhere to the stack-up. Laser skiving can then be done around the perimeter of the cavity, and buildup layers above the release layer 451 can be removed mechanically. In other embodiments, the release layer 451 may be a thin layer of copper or other metal. The release layer 451 then functions as a laser stop. The entire cavity is then skived to remove the buildup layers. The release layer 451 may then be etched to electrically separate the pads 432. In another embodiment the release layer 451 is a continuous pad layer. The full cavity can be skived. The release layer 451 is then patterned to form the separate pads 432.

Referring now to FIG. 4C, a cross-sectional illustration of the electronic package 400 after additional routing layers are formed is shown, in accordance with an embodiment. In an embodiment, three additional routing layers are provided over the top routing layers above the core 406 shown in FIG. 4B. A single additional routing layer is provided over the bottom routing layers below the core 406. However, it is to be appreciated that any number of additional routing layers may be provided over and/or below the core 406.

In an embodiment, the buildup layers 431 above the release layer 451 are without conductive routing. This is because the buildup layers 431 above the release layer 451 will ultimately be removed to make the first plateau on which the first die will be placed. Conductive routing (e.g., pads 432, vias 433, and the like) may be provided in the buildup layers 431 adjacent to the release layer 451. In an embodiment, openings 441 may be provided through the buildup layers 431 to expose pads 432 that are buried below the top surface. The openings 441 may be used to connect the second die (added in a subsequent processing operation) to the pads 432.

Referring now to FIG. 4D, a cross-sectional illustration of the electronic package 400 after a solder resist layer 435 is disposed over a top buildup layer 431 is shown, in accordance with an embodiment. As shown, the solder resist layer 435 covers only a portion of the top surface of the topmost buildup layer 431. In an embodiment, the solder resist layer 435 provides the surface for the third plateau on which a third die (added in a subsequent processing operation) is placed.

In an embodiment, interconnects 452 may be provided through solder resist openings to connect to a top pad 432. The interconnect 452 may be a first level interconnect (FLI), such as a solder or the like. Similarly, interconnects 453 may be provided through the openings 441 in order to provide electrical connection to the buried pads 432. The interconnects 453 may be used to connect the package substrate 405 to a second die (added in a subsequent processing operation). The interconnects 453 may be FLI interconnects, such as solder or the like.

Referring now to FIG. 4E, a cross-sectional illustration of the electronic package 400 after the release layer 451 is exposed is shown, in accordance with an embodiment. In an embodiment, the buildup layers 431 above the release layer 451 may be removed with any suitable process to form a cavity. For example, a laser skiving process or an etching process may be used to remove the buildup layers 431 and form the cavity.

After the exposure of the release layer 451, three distinct regions 461, 462, and 463 are provided. The first region 461 includes a first plateau 421 at the bottom of the cavity, the second region 462 includes a second plateau 422, and the third region 463 includes a third plateau 423. In an embodiment, the first plateau 421 comprises the recessed buildup layers 431, the second plateau 422 comprises the top buildup layer 431, and the third plateau 423 comprises the solder resist layer 435.

As shown, the vertical distance between the plateaus 421, 422, and 423 may be non-uniform. For example, a vertical distance between the first plateau 421 and the second plateau 422 is greater than a vertical distance between the second plateau 422 and the third plateau 423. This is to accommodate dies with different Z-heights. It is to be appreciated that in other embodiments, the vertical distances between plateaus 421, 422, and 423 may be substantially uniform, or the vertical distance between the first plateau 421 and the second plateau 422 may be smaller than the vertical distance between the second plateau 422 and the third plateau 423.

Referring now to FIG. 4F, a cross-sectional illustration of the electronic package 400 after the release layer 451 is removed is shown, in accordance with an embodiment. In an embodiment, the release layer 451 may be removed with a release process, a stripping process, or an etching process. Removal of the release layer 451 provides access to the pads 432 on the first plateau 421. Additionally, openings 464 may be formed to expose backside pads.

Referring now to FIG. 4G, a cross-sectional illustration of the electronic package 400 after a first die 401 is placed over the first plateau 421 is shown, in accordance with an embodiment. In an embodiment, the first die 401 may be a PIC, though it is to be appreciated that other die types may also be used. In an embodiment, pads 407 of the first die 401 are connected to the pads 432 on the first plateau 421 by a solder 454 or other interconnect architecture. That is, the first die 401 may be electrically coupled to the package substrate 405. In an embodiment, top pads 408 may be provided on a top surface of the first die 401. The top pads 408 may be used to couple the first die 401 to a second die (attached in a subsequent processing operation).

In an embodiment, an edge of the first die 401 may be substantially coplanar with an edge of the package substrate 405. In other embodiments, the first die 401 may extend out past an edge of the package substrate 405 so that an edge of the package substrate 405 is not substantially coplanar with the edge of the package substrate 405. In an embodiment, a z-position of the top surface of the first die 401 may be proximate to the z-position of the second plateau 422. However, it is to be appreciated that the top surface of the first die 401 need not be substantially coplanar with the second plateau 422. For example, in FIG. 4G, the top surface of the first die 401 is above the second plateau 422. In other embodiments, the top surface of the first die 401 may be below the second plateau 422.

In an embodiment, the first die 401 may be surrounded by an underfill material 455. The underfill material 455 may be any common underfill material typical of electronic packaging. In addition to providing support to the solder 454, the underfill material 455 may also be provided between a sidewall of the first die 401 and the vertical sidewall of the package substrate 405 between the first plateau 421 and the second plateau 422.

Referring now to FIG. 4H, a cross-sectional illustration of the electronic package 400 after a second die 402 is attached to the second plateau 422 is shown, in accordance with an embodiment. In an embodiment, the second die 402 may be an EIC, though it is to be appreciated that the second die may be any type of die. The second die 402 may be positioned on the second plateau 422 so that a portion of the second die 402 extends over a portion of the first die 401. The second die 402 may comprise pads 409. The pads 409 may be electrically coupled to the pads 408 on the top surface of the first die 401 by interconnects 456. As such, the first die 401 may be directly coupled to the second die 402 without the need for an intervening bridge. Additionally, since the second die 402 overlaps a portion of the first die 401, the total area is reduced compared to embodiments that use a bridge to connect the first die 401 to the second die 402.

In an embodiment, pads 411 on the second die 402 may be coupled with interconnects 453 on the package substrate 405. That is, a bottom surface of the second die 402 may be electrically coupled to both the first die 401 and the package substrate 405. In an embodiment, pads 412 may be provided on a top surface of the second die 402. An underfill material 457 may also encapsulate the second die 402.

In the illustrated embodiment, a thickness of the second die 402 is smaller than a thickness of the first die 401. However, it is to be appreciated that the second die 402 may have a similar thickness to the first die 401 or have a thickness that is greater than the first die 401. In instances where the second die 402 is thicker than what is shown in FIG. 4H, the second plateau 422 may be recessed deeper into the package substrate 405. For example, instead of the second plateau 422 being on the topmost buildup layer 431, the second plateau 422 may be one or more layers below the topmost buildup layer 431. In such cases, a release layer similar to the release layer 451 may be used to set the depth of the second plateau 422.

Referring now to FIG. 4I, a cross-sectional illustration of the electronic package 400 after a third die 403 is attached is shown, in accordance with an embodiment. In an embodiment, the third die 403 may be a logic die, such as an FPGA, a system on a chip (SOC), or any other type of die. The third die 403 may be provided on the third plateau 423. The third plateau 423 may be the top surface of the solder resist 435. In an embodiment, the third die 403 may also extend over a top surface of the second die 402. As shown, pads 413 on the third die 403 may be coupled to the top pads 412 on the second die 402 by interconnects 458, such as solder. Additionally, pads 414 on the bottom side of the third die 403 may be coupled to the package substrate 405 by interconnects 452, such as a solder. In an embodiment, an underfill material 459 may be disposed under and around the third die 403. In some embodiments, the underfill material 459 may have a characteristic sloped surface around a perimeter of the third die 403.

Referring now to FIG. 4J, a cross-sectional illustration of the electronic package 400 after an optical fiber 470 is coupled to the first die 401 is shown, in accordance with an embodiment. In embodiments where the first die 401 is a PIC, the optical fiber 470 may provide optical inputs to and/or receive optical outputs from the first die 401. That is, the optical fiber 470 provides an optical coupling to devices outside of the electronic package 400. While a single optical fiber 470 is shown, it is to be appreciated that a fiber bundle comprising a plurality of optical fibers may be coupled to the first die 401. In an embodiment, the optical fiber 470 may set into a v-groove 471 into the first die 401. However, it is to be appreciated that any optical coupling architecture (e.g., edge couplers, grating couplers, etc.) may be used to couple the optical fiber 470 to the first die 401. In an embodiment, a lens system may couple to the PIC before a fiber array is coupled to the PIC.

As will be described in greater detail below, the electronic package 400 in FIG. 4J may be subsequently coupled to a board (e.g., a printed circuit board (PCB) or the like). The electronic package 400 may be coupled to the board before attachment of the optical fiber 470 or after the attachment of the optical fiber 470.

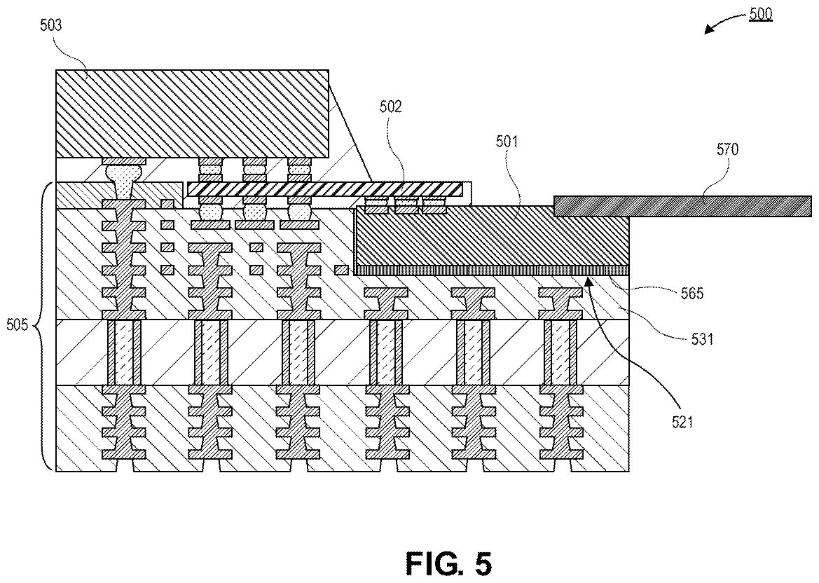

Referring now to FIG. 5, a cross-sectional illustration of an electronic package 500 is shown, in accordance with an additional embodiment. In an embodiment, the electronic package 500 may be substantially similar to the electronic package 400 described above with the exception of the coupling of the first die 501 to the package substrate 505. For example, the electronic package 500 may comprise a package substrate 505 with a first die 501 on a first plateau, a second die 502 on a second plateau, and a third die 503 on a third plateau. The first die 501 is directly coupled to the second die 502, and the second die 502 is directly coupled to the third die 503. An optical fiber 570 may be coupled to the first die 501. For example, the first die 501 may be a PIC, the second die 502 may be an EIC, and the third die 503 may be a logic die.

In contrast to the embodiments described above, the first die 501 may be attached to the buildup layer 531 by an adhesive 565, such as a die attach film (DAF). That is, there may not be an electrical connection between the bottom surface of the first die 501 and the package substrate 505, as is described above. Instead, the first die 501 may only include pads on a top surface that are coupled to the second die 502.

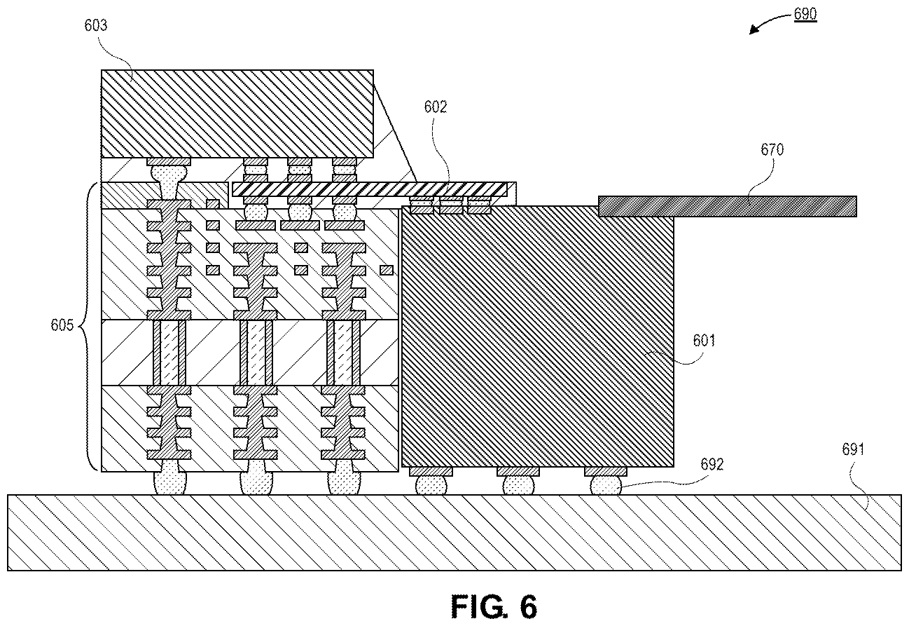

Referring now to FIG. 6, a cross-sectional illustration of an electronic system 690 is shown, in accordance with an additional embodiment. In an embodiment, the electronic system 690 may comprise a board 691, such as a PCB or the like. A package substrate 605 may be coupled to the board 691 by interconnects 692, such as solder balls, sockets or the like. In an embodiment, a second die 602 and a third die 603 are coupled to the package substrate 605. The second die 602 may be directly coupled to the third die 603 using a stepped architecture similar to embodiments described above. In an embodiment, the second die 602 may extend laterally past an edge of the package substrate 605.

In an embodiment, a first die 601 may be directly coupled to the board 691 by interconnects 692. The second die 602 may extend over the first die 601. Additionally, the second die 602 is directly coupled to the first die 601 by interconnects. That is, the first die 601 may not be on the package substrate 605 in some embodiments. In an embodiment, an optical fiber 670 is coupled to the first die 601.

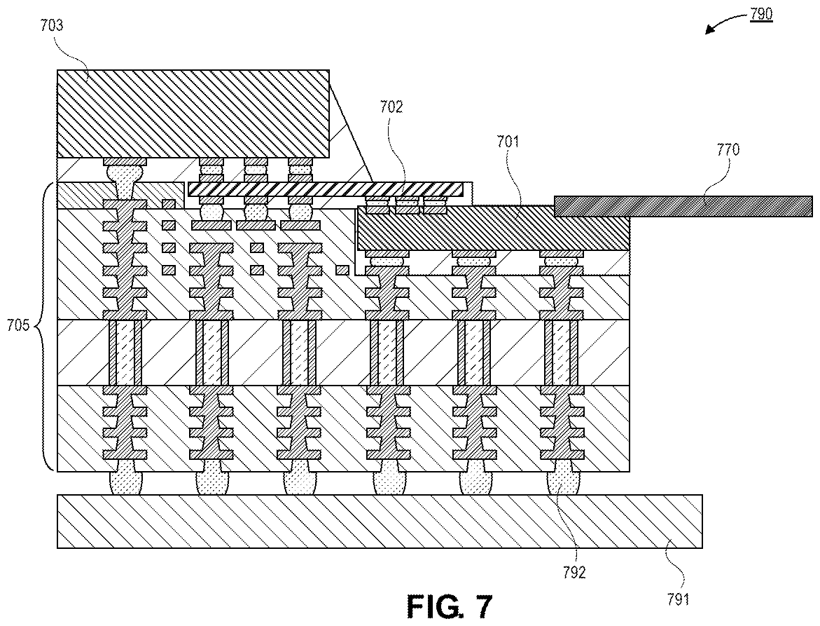

Referring now to FIG. 7, a cross-sectional illustration of an electronic system 790 is shown, in accordance with an additional embodiment. In an embodiment, the electronic system 790 may comprise a board 791, such as a PCB. In an embodiment, a package substrate 705 is coupled to the board 791 by interconnects 792, such as solder balls, sockets, or any other suitable interconnect architecture. In an embodiment, a plurality of dies 701, 702, and 703 are provided over a stepped top surface of the package substrate 705. For example, a first die 701 is provided over a first plateau, a second die 702 is provided over a second plateau, and a third die 703 is provided over a third plateau. The second die 702 extends over a top surface of the first die 701, and the second die 702 is directly coupled to the first die 701. The third die 703 extends over a top surface of the second die 702, and the third die 703 is directly coupled to the second die 702. As such, there is no need for embedded bridges to couple the dies together. The stacked architecture reduces the total footprint of the dies 701, 702, and 703, and the lack of embedded bridges decreases power loss.

In an embodiment, the first die 701 may be a PIC, the second die 702 may be an EIC, and the third die 703 may be a logic die. Though it is to be appreciated that embodiments are not limited to such die types. In an embodiment, an optical fiber 770 is coupled to the first die 701.

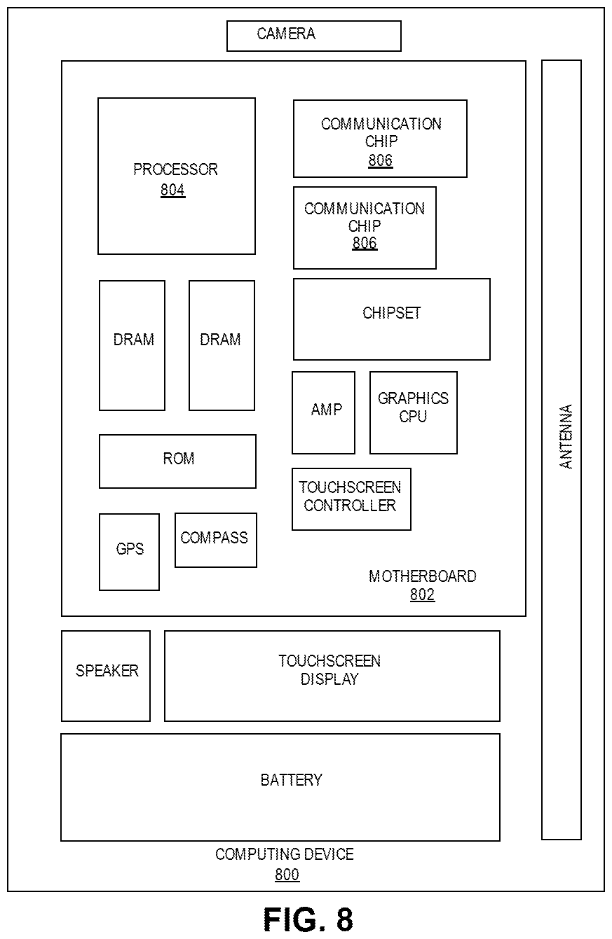

FIG. 8 illustrates a computing device 800 in accordance with one implementation of the invention. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In some implementations of the invention, the integrated circuit die of the processor may be part of an electronic package that comprises a stepped top surface with a plurality of dies on different plateaus that are directly coupled to each other, in accordance with embodiments described herein. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In accordance with another implementation of the invention, the integrated circuit die of the communication chip may be part of an electronic package that comprises a stepped top surface with a plurality of dies on different plateaus that are directly coupled to each other, in accordance with embodiments described herein.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: an electronic package, comprising: a package substrate with a stepped top surface; a first die on a first plateau of the stepped top surface; a second die on a second plateau of the stepped top surface, wherein the second die extends over the first die; and a third die on a third plateau of the stepped top surface, wherein the third die extends over the second die.

Example 2: the electronic package of Example 1, wherein the first die is a photonics integrated circuit, the second die is an electrical integrated circuit, and the third die is a logic die.

Example 3: the electronic package of Example 1 or Example 2, wherein the third die is communicatively coupled to the second die, and wherein the second die is communicatively coupled to the first die.

Example 4: the electronic package of Examples 1-3, wherein the first die is coupled to the package substrate by a solder.

Example 5: the electronic package of Examples 1-3, wherein the first die is attached to the package substrate by a die attach film.

Example 6: the electronic package of Examples 1-5, wherein the second die comprises through substrate vias.

Example 7: the electronic package of Example 6, wherein the through substrate vias are positioned over the first die.

Example 8: the electronic package of Example 6, wherein the through substrate vias are positioned below the third die.

Example 9: the electronic package of Examples 1-8, wherein a thickness of the second die is greater than one routing layer in the electronic package.

Example 10: the electronic package of Examples 1-9, further comprising: an optical fiber coupled to the first die.

Example 11: the electronic package of Examples 1-10, further comprising a fourth die on a fourth plateau of the stepped top surface, wherein the fourth die extends over the third die.

Example 12: an electronic system, comprising: a board; a package substrate coupled to the board, wherein the package substrate comprises a bottom surface and a stepped top surface; a first die coupled to the board and adjacent to the package substrate; a second die on a first plateau of the stepped top surface of the package substrate, wherein the second die extends over the first die; and a third die on a second plateau of the stepped top surface of the package substrate, wherein the third die extends over the second die.

Example 13: the electronic system of Example 12, wherein the first die is a photonics integrated circuit, the second die is an electrical integrated circuit, and the third die is a logic die.

Example 14: the electronic system of Example 12 or Example 13, further comprising: an optical fiber coupled to the first die.

Example 15: the electronic system of Examples 12-14, wherein the package substrate comprises a core.

Example 16: the electronic system of Examples 12-15, wherein the third die is communicatively coupled to the second die, and wherein the second die is communicatively coupled to the first die.

Example 17: the electronic system of Examples 12-16, wherein a thickness of the second die is greater than one routing layer in the electronic package.

Example 18: a method of forming an electronic package, comprising: forming first routing layers over a package core; disposing a release layer over a portion of a topmost first routing layer; forming second routing layers over the first routing layers; forming a solder resist layer over a portion of a topmost second routing layer; opening a cavity through the second routing layers, wherein a cavity bottom is at the release layer; positioning a first die in the cavity; positioning a second die over the first die and over a topmost second routing layer; and positioning a third die over the second die and over the solder resist layer.

Example 19: the method of Example 18, wherein the first die is a photonics integrated circuit, the second die is an electrical integrated circuit, and the third die is a logic die.

Example 20: the method of Example 18 or Example 19, wherein the first die is connected to the package substrate by solder.

Example 21: the method of Examples 18-20, wherein the first die is attached to the package substrate by a die attach film.

Example 22: the method of Examples 18-21, wherein the electronic package is coupled to a board.

Example 23: an electronic system, comprising: a board; and an electronic package coupled to the board, wherein the electronic package comprises: a package substrate with a stepped top surface; a first die on a first plateau of the stepped top surface; a second die on a second plateau of the stepped top surface, wherein the second die extends over the first die; and a third die on a third plateau of the stepped top surface, wherein the third die extends over the second die.

Example 24: the electronic system of Example 23, wherein the first die is a photonics integrated circuit, the second die is an electrical integrated circuit, and the third die is a logic die.

Example 25: the electronic system of Example 23 or Example 24, wherein a thickness of the second die is greater than one routing layer in the electronic package.

What is claimed is:

1. An electronic package, comprising:
a package substrate with a stepped top surface;
a first die on a first plateau of the stepped top surface;
a second die on a second plateau of the stepped top surface, wherein the second die extends over the first die; and
a third die on a third plateau of the stepped top surface, wherein the third die extends over the second die.

2. The electronic package of claim 1, wherein the first die is a photonics integrated circuit, the second die is an electrical integrated circuit, and the third die is a logic die.

3. The electronic package of claim 1, wherein the third die is communicatively coupled to the second die, and wherein the second die is communicatively coupled to the first die.

4. The electronic package of claim 1, wherein the first die is coupled to the package substrate by a solder.

5. The electronic package of claim 1, wherein the first die is attached to the package substrate by a die attach film.

6. The electronic package of claim 1, wherein the second die comprises through substrate vias.

7. The electronic package of claim 6, wherein the through substrate vias are positioned over the first die.

8. The electronic package of claim 6, wherein the through substrate vias are positioned below the third die.

9. The electronic package of claim 1, wherein a thickness of the second die is greater than one routing layer in the electronic package.

10. The electronic package of claim 1, further comprising:
an optical fiber coupled to the first die.

11. The electronic package of claim 1, further comprising a fourth die on a fourth plateau of the stepped top surface, wherein the fourth die extends over the third die.

12. An electronic system, comprising:
a board;
a package substrate coupled to the board, wherein the package substrate comprises a bottom surface and a stepped top surface;
a first die coupled to the board and adjacent to the package substrate;
a second die on a first plateau of the stepped top surface of the package substrate, wherein the second die extends over the first die; and
a third die on a second plateau of the stepped top surface of the package substrate, wherein the third die extends over the second die.

13. The electronic system of claim 12, wherein the first die is a photonics integrated circuit, the second die is an electrical integrated circuit, and the third die is a logic die.

14. The electronic system of claim 12, further comprising:
an optical fiber coupled to the first die.

15. The electronic system of claim 12, wherein the package substrate comprises a core.

16. The electronic system of claim 12, wherein the third die is communicatively coupled to the second die, and wherein the second die is communicatively coupled to the first die.

17. The electronic system of claim 12, wherein a thickness of the second die is greater than one routing layer in the electronic package.

18. A method of forming an electronic package, comprising:
forming first routing layers over a package core;
disposing a release layer over a portion of a topmost first routing layer;
forming second routing layers over the first routing layers;
forming a solder resist layer over a portion of a topmost second routing layer;
opening a cavity through the second routing layers, wherein a cavity bottom is at the release layer;
positioning a first die in the cavity;
positioning a second die over the first die and over a topmost second routing layer; and
positioning a third die over the second die and over the solder resist layer.

19. The method of claim 18, wherein the first die is a photonics integrated circuit, the second die is an electrical integrated circuit, and the third die is a logic die.

20. The method of claim 18, wherein the first die is connected to the package substrate by solder.

21. The method of claim 18, wherein the first die is attached to the package substrate by a die attach film.

22. The method of claim 18, wherein the electronic package is coupled to a board.

23. An electronic system, comprising:
a board; and
an electronic package coupled to the board, wherein the electronic package comprises:
a package substrate with a stepped top surface;
a first die on a first plateau of the stepped top surface;
a second die on a second plateau of the stepped top surface, wherein the second die extends over the first die; and
a third die on a third plateau of the stepped top surface, wherein the third die extends over the second die.

24. The electronic system of claim 23, wherein the first die is a photonics integrated circuit, the second die is an electrical integrated circuit, and the third die is a logic die.

25. The electronic system of claim 23, wherein a thickness of the second die is greater than one routing layer in the electronic package.
